(19) United States
(12) Patent Application Publication
(10) Pub. No.: US 2024/0053407 A1
(43) Pub. Date: Feb. 15, 2024

(54) METHOD FOR ESTIMATING INTERNAL RESISTANCE OF LITHIUM BATTERY, STORAGE MEDIUM, AND ELECTRONIC DEVICE

(71) Applicant: Shanghai Makesens Energy Storage Technology Co., Ltd., Shanghai (CN)

(72) Inventors: Guopeng ZHOU, Shanghai (CN); Xiaohua CHEN, Shanghai (CN); Enhai ZHAO, Shanghai (CN); Xiao YAN, Shanghai (CN)

(73) Assignee: Shanghai Makesens Energy Storage Technology Co., Ltd., Shanghai (CN)

(21) Appl. No.: 18/229,684

(22) Filed: Aug. 3, 2023

(30) Foreign Application Priority Data
Aug. 10, 2022 (CN) 2022109570861

(51) Int. Cl. G01R 31/389

(52) U.S. Cl. CPC G01R 31/389

(57) ABSTRACT

A method for estimating an internal resistance of a lithium battery, a storage medium, and an electronic device are provided. The method includes: sampling a current and a voltage of the lithium battery at a preset sampling interval; inputting the current and the voltage of the lithium battery to an internal resistance estimation equivalent circuit model, determining to-be-estimated parameters of the model, and determining expressions of an open circuit voltage and an internal resistance of the battery; obtaining a range of each of the to-be-estimated parameters of the model based on a memory factor of the model; and inputting the range of each of the to-be-estimated parameters to an internal resistance distribution model to obtain a total internal resistance of the battery, and determining a distribution of the total internal resistance by repeatedly running the internal resistance distribution model, to obtain different estimated values of the total internal resistance.

### CROSS REFERENCE TO RELATED APPLICATION

The present application claims the benefit of priority to Chinese Patent Application No. CN 202210957086.1, entitled “METHOD FOR ESTIMATING INTERNAL RESISTANCE OF LITHIUM BATTERY, STORAGE MEDIUM, AND ELECTRONIC DEVICE”, filed with CNIPA on Aug. 10, 2022, the disclosure of which is incorporated herein by reference in its entirety for all purposes.

### FIELD OF THE INVENTION

The present disclosure belongs to the technical field of battery parameter estimation, and relates to a method for estimating an internal resistance, and in particular, to a method for estimating an internal resistance of a lithium battery, a storage medium, and an electronic device.

### BACKGROUND OF THE INVENTION

As new-energy vehicles or energy storage stations are used, the internal resistance of their lithium batteries gradually increases after multiple charges and discharges. This change in internal resistance affects the battery's aging and heat generation. When a battery pack is charged and discharged under consistent conditions, inconsistent internal resistance among individual batteries can result in different heat power losses, affecting the entire battery pack's lifespan. To better manage the batteries and prevent or avoid problems, it's necessary to predict and estimate the batteries' internal resistance.

Currently, most methods for estimating an internal resistance of a battery are based on data sets from stable operating conditions and require high-quality data. When applied to various working environments, such as a non-constant-current working environment or a frequency regulation working environment, current methods lead to a significant increase in estimation error. It's also challenging to estimate the internal resistance in various working environments in real-time.

Therefore, how to accurately estimate the internal resistance of a battery in various working environments has become an urgent technical problem to be solved by those skilled in the art.

### SUMMARY OF THE INVENTION

An aspect of the present disclosure provides a method for estimating an internal resistance of a lithium battery. The method comprises: S11: continuously sampling a current and a voltage of the lithium battery at a preset sampling interval; S12: inputting the current and the voltage of the lithium battery to a previously constructed internal resistance estimation equivalent circuit model, determining to-be-estimated parameters of the internal resistance estimation equivalent circuit model, and determining expressions of an open circuit voltage and an internal resistance of the lithium battery comprising the to-be-estimated parameters; S13: obtaining a range of each of the to-be-estimated parameters of the internal resistance estimation equivalent circuit model based on an adaptively adjusted memory factor of the internal resistance estimation equivalent circuit model; and S14: S14A, inputting the range of each of the to-be-estimated parameters to an internal resistance distribution model to obtain a total internal resistance of the lithium battery, and S14B, determining a statistical distribution of the total internal resistance of the lithium battery by repeatedly running the internal resistance distribution model, with different numbers of single estimations carried out during each repetition of running the internal resistance distribution model, to obtain different estimated values of the total internal resistance of the lithium battery.

In an embodiment of the present disclosure, S12 further comprises: inputting the current and the voltage of the lithium battery to an input matrix of the internal resistance estimation equivalent circuit model; and completing iterative calculation of the internal resistance estimation equivalent circuit model by using the adaptively adjusted memory factor, to determine the expressions of the open circuit voltage and the internal resistance of the lithium battery, wherein the expression of the open circuit voltage is obtained by polynomial fitting, which is a polynomial of the open circuit voltage.

In an embodiment of the present disclosure, S13 further comprises: adjusting the adaptively adjusted memory factor to determine ranges of polynomial coefficients of each order in the polynomial of the open circuit voltage.

In an embodiment of the present disclosure, the internal resistance is the total internal resistance, and comprises an ohmic internal resistance and a polarization internal resistance, wherein the internal resistance distribution model comprises a particle swarm optimization (PSO) model, wherein S14A comprises: S14A1, deriving an expression of a terminal voltage which is a function of the total internal resistance and the ranges of the polynomial coefficients, wherein the expression of the terminal voltage serves as an objective function; and S14A2, continuously moving and adjusting each particle of the PSO model within the ranges of the polynomial coefficients, and determining the total internal resistance of the lithium battery according to a corresponding value of the objective function.

In an embodiment of the present disclosure, the corresponding value of the objective function is a difference between the terminal voltage and the voltage sampled at S11, wherein S14A2 comprises: continuously moving and adjusting each particle within the ranges of the polynomial coefficients until a smallest difference between the terminal voltage and the voltage sampled at S11 is obtained; and for each particle, using its present position corresponding to the smallest difference as an optimal position of the particle, and using corresponding values of the polynomial coefficients as optimal solutions, which are then substituted into the expression of the internal resistance to obtain a value of the total internal resistance of the lithium battery.

In an embodiment of the present disclosure, S14B comprises: using the different estimated values of the total internal resistance obtained through each estimation as a horizontal axis, and using frequencies of occurrence of the different values of the total internal resistance as a vertical axis, wherein each frequency of occurrence is a number of times a corresponding estimated value of the total internal resistance occurs during estimation divided by a total number of single estimations carried out; and treating a distribution of the estimated values of the total internal resistance obtained through estimation as a normal distribution, and taking an expected value of the normal distribution as an expected internal resistance of the battery.

In an embodiment of the present disclosure, after S14B, the method for estimating an internal resistance of a lithium battery further comprises: using a change in the expected value of the normal distribution as a change in the total internal resistance as the lithium battery charges and discharges; and analyzing a deterioration trend of the lithium battery through the change in the total internal resistance.

In an embodiment of the present disclosure, S11 further comprises: creating the internal resistance estimation equivalent circuit model by using a first-order RC equivalent circuit, wherein the internal resistance estimation equivalent circuit model comprises mathematical models for the open circuit voltage and the internal resistance of the lithium battery.

Another aspect of the present disclosure provides a computer-readable storage medium, storing a computer program, and when the computer program is executed by a processor, the method for estimating an internal resistance of a lithium battery is implemented.

Another aspect of the present disclosure provides an electronic device, comprising: a processor and a memory, wherein the memory is configured to store a computer program, and the processor is configured to execute the computer program stored in the memory, so that the electronic device performs the method for estimating an internal resistance of a lithium battery.

As described above, the method for estimating an internal resistance of a lithium battery, the storage medium, and the electronic device of the present disclosure have the following beneficial effects.

(1) The present disclosure may be applied to various working environments, and is able to accurately estimate the internal resistance of the battery in various working environments. For example, the present disclosure can be applied in a non-constant-current/voltage working environment.

(2) The internal resistance estimation of the present disclosure has high accuracy, and the internal resistance distribution of the battery can be accurately obtained from test results. When the distribution of the internal resistance of the battery satisfies a normal distribution, it may be considered that the expected value of the distribution is the internal resistance of the battery.

(3) Implementation of the method of the present disclosure requires a very small memory space of only 15 kB, and doesn't interfere with other functions during practical application. It also operates quickly in real-time. For example, it takes only about 2 seconds to process a whole day's data for a single battery using the method.

### BRIEF DESCRIPTION OF THE DRAWINGS

FIG. 1 is a schematic flowchart of a method for estimating an internal resistance of a lithium battery according to an embodiment of the present disclosure.

FIG. 2 is an equivalent circuit model diagram of a method for estimating an internal resistance of a lithium battery according to an embodiment of the present disclosure.

FIG. 3 is a statistical distribution diagram of internal resistance of a method for estimating an internal resistance of a lithium battery according to an embodiment of the present disclosure.

FIG. 4 is a schematic diagram showing a structural connection of an electronic device according to an embodiment of the present disclosure.

### REFERENCE NUMERALS

4 Electronic Device
41 Processor
42 Memory
S11-S14 Steps

### DETAILED DESCRIPTION

Implementations of the present disclosure are described below through specific examples, and a person skilled in the art can easily understand other advantages and effects of the present disclosure from the contents disclosed in this specification. The present disclosure may further be implemented or applied through other different specific implementations, and various details in this specification may also be modified or changed based on different viewpoints and applications without departing from the spirit of the present disclosure. It should be noted that the following embodiments and features in the embodiments may be combined with each other in case of no conflicts.

It should be noted that, the drawings accompanying the following embodiments show the basic idea of the present disclosure in a schematic manner, and only components closely related to the present disclosure are shown in the drawings. The drawings are not necessarily drawn according to the number, shape, and size of the components in actual implementation; during the actual implementation, the type, quantity, and proportion of each component can be changed as needed, and the layout of the components can also be more complicated.

Through the method for estimating an internal resistance of a lithium battery, the storage medium, the electronic device of the present disclosure, accuracy of internal resistance estimation for a battery can be ensured in various operating environments, and good applicability can be achieved in various operating environments.

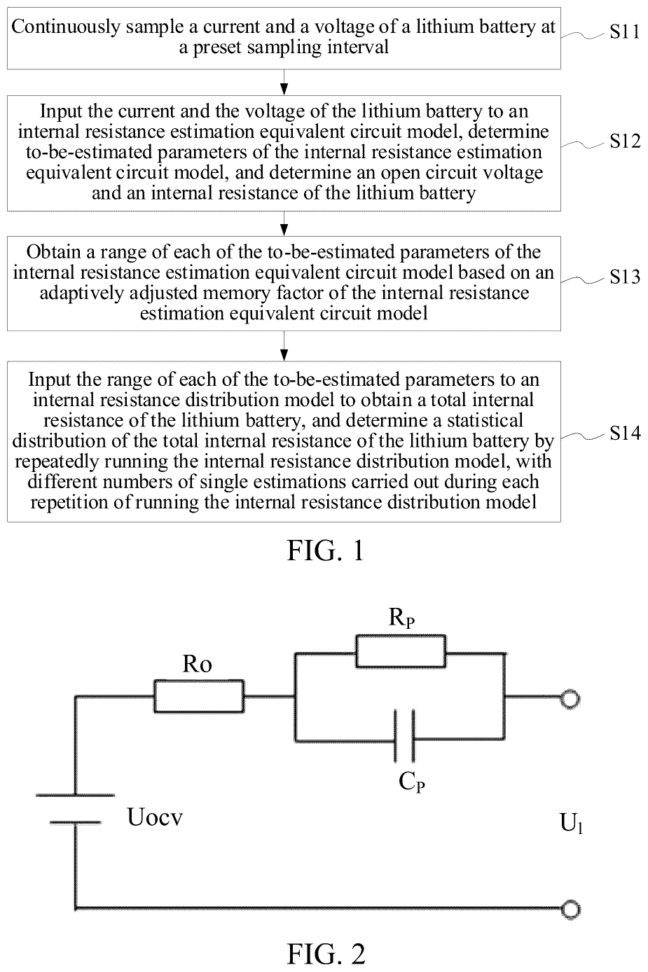

The principle and implementation of the method for estimating the internal resistance of the lithium battery, the storage medium, and the electronic device of the present disclosure are to be described in detail with reference to FIG. 1 to FIG. 4, so that a person skilled in the art can understand them without creative efforts.

Refer to FIG. 1, which is a schematic flowchart of a method for estimating an internal resistance of a lithium battery according to an embodiment of the present disclosure. As shown in FIG. 1, the method comprises steps S11-S14.

S11: Continuously sampling a current and a voltage of the lithium battery at a preset sampling interval.

Specifically, battery data of a power station or an electric vehicle containing the lithium battery is sampled at regular intervals and uploaded. The data sampled at S11 mainly comprises an operating time, a current, a voltage, a temperature, a state of charge (SOC) of the lithium battery, and the like. In practical applications, the preset sampling interval may be more than ten seconds or another proper interval.

In an embodiment, during step S11, the method further comprises: creating an internal resistance estimation equivalent circuit model by using a first-order RC equivalent circuit, wherein the internal resistance estimation equivalent circuit model comprises mathematical models for an open circuit voltage and the internal resistance of the lithium battery.

Refer to FIG. 2, which is an equivalent circuit model diagram according to an embodiment of the present disclosure. As shown in FIG. 2, the first-order RC equivalent circuit is adopted, and the corresponding formulas of the internal resistance estimation equivalent circuit model are as follows:

$$\dot{{U}_{p}} = \frac{{U}_{p}}{{R}_{p} {C}_{p}} + \frac{{i}_{l}}{{C}_{p}} \\ {U}_{l} = {U}_{ocv} - {U}_{p} - {i}_{l} {R}_{o}$$

Uₗ represents a terminal voltage of the battery, U_{ocv} represents an open circuit voltage of the battery, Uₚ represents a polarization voltage of the battery, and iₗ represents a current of the battery.

Then a transfer function based on the internal resistance estimation equivalent circuit model is given by:

$$G ( s ) = \frac{{U}_{l} ( s ) - {U}_{ocv} ( s )}{{i}_{l} ( s )} = - ( {R}_{o} + \frac{{R}_{p}}{1 + {R}_{p} {C}_{p} s} ) ,$$

which is equivalent to

$${U}_{l} ( s ) - {U}_{ocv} ( s ) = - {i}_{l} ( s ) ( {R}_{o} + \frac{{R}_{p}}{1 + {R}_{p} {C}_{p} s} )$$

S12: Inputting the current and the voltage of the lithium battery to the previously constructed internal resistance estimation equivalent circuit model, determining to-be-estimated parameters of the internal resistance estimation equivalent circuit model, and determining expressions of the open circuit voltage and the internal resistance of the lithium battery comprising the to-be-estimated parameters.

In an embodiment, S12 further comprises the following steps.

(1) Inputting the current and the voltage of the lithium battery to an input matrix of the internal resistance estimation equivalent circuit model.

Specifically, based on bilinear transformation, the transfer function of the internal resistance estimation equivalent circuit model is transformed into:

δU_{l,k}=a₁×δU_{l,k-1}+a₂×i_{l,k}+a₃×i_{l,k-1}
a₁, a₂, and a₃ are coefficients related to model parameters, which vary in the process of parameter estimation. δU_{l,k}=U_{l,k}−U_{ocv,k} represents a difference between the battery terminal voltage and the open circuit voltage during the kth sampling. The open circuit voltage U_{ocv} is associated with the SOC and temperature of the battery. Since the sampling interval is very short, for example, 15 s, changes of the SOC and temperature between adjacent sampling intervals are neglectable, and therefore it is assumed that U_{ocv,k}=U_{ocv,k-1}, and therefore, the above bilinear transformation formula is converted into

U_{l,k}=(1−a₁)×U_{ocv,k}+a₁×U_{l,k-1}+a₂×i_{l,k}+a₃×i_{l,k-1}

Then a to-be-estimated-parameter matrix xₖ (parameter matrix, for short) and an input variable matrix Aₖ are determined to be given by:

xₖ=[(1−a₁)U_{ocv,k}a₁a₂a₃]^{T}

Aₖ=[1U_{l,k-1},i_{l,k}i_{l,k-1}]^{T}
U_{l,k-1} represents a terminal voltage at a moment k−1, i_{l,k} represents a current at a moment k, and i_{l,k-1} represents a current at the moment k−1. These input variables are all obtained by sampling.

Then U_{ocv} and the internal resistance of the battery may be expressed as follows:

$${U}_{ocv , k} = \frac{{x}_{k} [ 0 ]}{1 - {a}_{1}} \\ {R}_{o} = \frac{{a}_{3} - {a}_{2}}{1 + {a}_{1}} \\ {R}_{o} + {R}_{p} = \frac{- {a}_{2} - {a}_{3}}{1 - {a}_{1}}$$

(2) Completing iterative calculation of the internal resistance estimation equivalent circuit model by using an adaptively adjusted memory factor, to determine the expressions of the open circuit voltage and the internal resistance of the lithium battery, wherein the expression of the open circuit voltage is obtained by polynomial fitting, which is a polynomial of the open circuit voltage.

Specifically, the parameter matrix xₖ is based on an adaptive memory-factor-recursive-least-squares (MFRLS) method. In order to ensure the stability of results, the adaptively adjusted memory factor λ is introduced to indicate a degree to which an estimation result of a previous moment is memorized. After the initial value of λ is set, λ is adjusted adaptively during each iteration based on set conditions, and the value of A is always between 0.9 and 1 in the adaptive process. The specific iterative calculation process is given as follows:

$${K}_{k} = {P}_{k - 1} {{A}_{k}^{T} [ {A}_{k} {P}_{k - 1} {A}_{k}^{T} + λ ]}^{- 1} \\ {\hat{x}}_{k} = {\hat{x}}_{k - 1} + {K}_{k} [ {U}_{l , k} - {A}_{k} {\hat{x}}_{k - 1} ] \\ {P}_{k} = \frac{1}{λ} [ I - {K}_{k} {A}_{k} ] {P}_{k - 1}$$

Pₖ is a covariance matrix of state estimation errors, Kₖ is the gain of each iteration, and I is an identity matrix.

S13: Obtaining a range of each of the to-be-estimated parameters of the internal resistance estimation equivalent circuit model based on the adaptively adjusted memory factor of the internal resistance estimation equivalent circuit model.

In an embodiment, the adaptively adjusted memory factor is adjusted to determine ranges of the polynomial coefficients of each order in a polynomial of the open circuit voltage.

In another embodiment, during repeated calculation of the to-be-estimated parameters, the adaptively adjusted memory factor is given different initial values to determine the ranges of the polynomial coefficients of each order in the polynomial of the open circuit voltage.

In another embodiment, during repeated calculation of the to-be-estimated parameters, the adaptively adjusted memory factor is given different initial values, and the adaptively adjusted memory factor is adjusted during the estimation, to determine the ranges of the polynomial coefficients of each order in the polynomial of the open circuit voltage.

Specifically, the current, the voltage, the SOC, and the temperature obtained through each sampling are inputted into a particle model to realize real-time parameter estimation, and a total internal resistance distribution of the battery is obtained based on estimated parameters.

An ohmic internal resistance, a polarization internal resistance, and a total internal resistance are obtained through estimation, wherein the total internal resistance comprises the ohmic internal resistance and the polarization internal resistance. The ohmic internal resistance and the polarization internal resistance fluctuate greatly when a particle swarm optimization (PSO) algorithm is used, but a sum of the ohmic internal resistance and the polarization internal resistance is unchanged, that is, the distribution of the total internal resistance remains unchanged. In addition, U_{ocv} is obtained, and the SOC-OCV curve is obtained by the following polynomial as described in step (2) in S12.

$${U}_{ocv} ( SOC ) = {\sum }_{n = 0}^{7} {b}_{n} \times {SOC}^{n}$$

n is the degree of the polynomial, bₙ is a coefficient of an nth order term of the polynomial, and bₙ is to be solved. During the estimation, λ has different initial values, and a value of U_{ocv} obtained from each estimation is substituted into the above formula to find the coefficients of the polynomial, to finally determine a range of each coefficient.

In practical application, for each coefficient, such as b₁, by adjusting the adaptively adjusted memory factor, different results are obtained through estimation. These results are arranged in the order from small to large, that is, a value range of the coefficient b₁ is between its minimum value and maximum value.

S14: Inputting the range of each of the to-be-estimated parameters to an internal resistance distribution model to obtain a total internal resistance of the lithium battery, and determine a statistical distribution of the total internal resistance of the lithium battery by repeatedly running the internal resistance distribution model, with different numbers of single estimations carried out during each repetition of running the internal resistance distribution model, to obtain different estimated values of the total internal resistance of the lithium battery.

In an embodiment, the internal resistance is a total internal resistance, and comprises an ohmic internal resistance and a polarization internal resistance. The internal resistance distribution model comprises a PSO model. The step of inputting the range of each of the to-be-estimated parameters to the internal resistance distribution model to obtain the total internal resistance of the lithium battery is defined as step A of S14, comprising A1 and A2.

(A1) Deriving an expression of a terminal voltage which is a function of the total internal resistance and the ranges of the polynomial coefficients, wherein the expression of the terminal voltage serves as an objective function.

Specifically, the PSO algorithm is used for estimating the statistical distribution of the internal resistance of the battery.

The PSO algorithm is used for finding an optimal solution through cooperation and information sharing among individuals in the group. The PSO algorithm requires each particle to maintain two vectors during optimizing, that is, a velocity vector and a position vector. i represents a serial number of one of the particles, and m is a number of to-be-solved parameters. The velocity of the particle determines a movement direction and a movement velocity of the particle, while the position reflects a position of a solution represented by the particle in the solution space, which is the basis for evaluating quality of the solution. The algorithm also requires each particle to maintain its own historical optimal position pBest and the group to maintain a global optimal gBest.

The velocity and the position of an ith particle on an mth parameter are updated respectively according to the following formulas:

vᵢ^{m}=ω×vᵢ^{m}+c₁×rand(0,1)×(pBestᵢ^{m}−xᵢ^{m})+c₂×rand(0,1)×(gBest^{m}−xᵢ^{m})

xᵢ^{m}=xᵢ^{m}+vᵢ^{m}

c₁ and c₂ are individual learning factors and social learning factors, so that the particles maintain movement inertia, and have the tendency to expand their search space and have the ability to explore new areas. Recommended values of c₁ and c₂ are between 1.5 and 2. ω is an inertia factor, which changes linearly during PSO search.

The to-be-calculated terminal voltage is used as the objective function, and the calculation formula of the terminal voltage is given by:

$${U}_{l} = {\sum }_{n = 0}^{7} {k}_{n} \times {SOC}^{n} - i \times R = {[ \begin{matrix}{k}_{0} & {k}_{1} & {k}_{2} & … & {k}_{7} & R\end{matrix} ] [ \begin{matrix}1 & {SOC}^{1} & {SOC}^{2} & … & {SOC}^{7} & - i\end{matrix} ]}^{T}$$

R is the total internal resistance of the battery. However, upper and lower limits of k₀, k₁, k₂, . . . , and k₇ are determined by the calculated range of bₙ.

(A2) Continuously moving and adjusting each particle of the PSO model within the ranges of the polynomial coefficients, and determining the total internal resistance of the lithium battery according to a corresponding value of the objective function. In practical application, the range of each parameter in the PSO algorithm is calculated by the recursive least squares.

Specifically, according to the calculation formula of the terminal voltage, the number of particles, iteration times, and c₁ and c₂ are adjusted, which is repeated for several times, and finally the statistical distribution of R is obtained.

In an embodiment, the value of the objective function is a difference between the terminal voltage and the voltage sampled at S11. Step (A2) of S14 comprises the following steps.

(A2.1) Continuously moving and adjusting each particle within the ranges of the polynomial coefficients until a smallest difference between the terminal voltage and the voltage sampled at S11 is obtained.

In practical application, an error between the estimated terminal voltage and the sampled voltage may be obtained by combining the voltage graph. When the estimated terminal voltage is very close to the sampled voltage, and the two curves almost coincide, it indicates that the difference between the terminal voltage and the voltage sampled at S11 is the smallest, and the method for estimating an internal resistance is reliable.

(A2.2) For each particle, using its present position corresponding to the smallest difference as an optimal position of the particle, and using corresponding values of the polynomial coefficients as optimal solutions, which are then substituted into the expression of the internal resistance to obtain a value of the total internal resistance of the lithium battery.

In an embodiment, the step of determining the statistical distribution of the total internal resistance of the lithium battery by repeatedly running the internal resistance distribution model is defined as step B of S14, comprising B1 and B2.

(B1) Using the different estimated values of the total internal resistance obtained through each estimation as a horizontal axis, and use frequencies of occurrence of the different values of the total internal resistance as a vertical axis. Each frequency of occurrence is a number of times a corresponding estimated value of the total internal resistance occurs during estimation divided by a total number of single estimations carried out.

In practical application, Table 1 is obtained by tabling the values of the internal resistance obtained through estimation, showing test and estimation results of the internal resistance of the battery, and it can be seen that the internal resistance gradually increases with the use of the battery. In order to assess the accuracy of real-time estimation of the internal resistance of the battery, a hybrid-pulse-power-characteristic (HPPC) test is used for testing the internal resistance of the battery for comparison with the internal resistance obtained through estimation. Specific results are shown in Table 1. Since the power station basically runs at a charge-discharge rate near 0.25C during operation, the HPPC result at 0.25C is taken for comparison. It may be seen from Table 1 that the total internal resistance of the battery has increased by 24% after 18 months of use. It may also be seen that the results of internal resistance estimation are different when A has different initial values, which indicates that it is necessary to obtain the statistical distribution of internal resistance of the battery.

TABLE 1
Test and estimation results of internal resistance of battery

| | | Initial | | | |
|---|---|---|---|---|---|
| Battery | | assigned | | | Ro + Rp/ |
| status | Condition | value of λ | Ro/mΩ | Rp/mΩ | mΩ |
| New | HPPC 0.25 C | / | 0.411 | 0.99 | 1.401 |
| battery | Estimation | 1 | 0.402 | 1.116 | 1.518 |
| | through MFRLS | 0.98 | 0.397 | 1.012 | 1.409 |
| | | 0.96 | 0.392 | 0.982 | 1.374 |
| | | 0.94 | 0.384 | 0.921 | 1.305 |
| 18 months | Estimation | 1 | 0.428 | 1.384 | 1.812 |
| of use | through MFRLS | 0.98 | 0.413 | 1.336 | 1.749 |
| | | 0.96 | 0.397 | 1.271 | 1.668 |
| | | 0.94 | 0.375 | 1.197 | 1.572 |
| 24 months | Estimation | 0.98 | 0.429 | 1.548 | 1.977 |
| of use | through MFRLS | | | | |

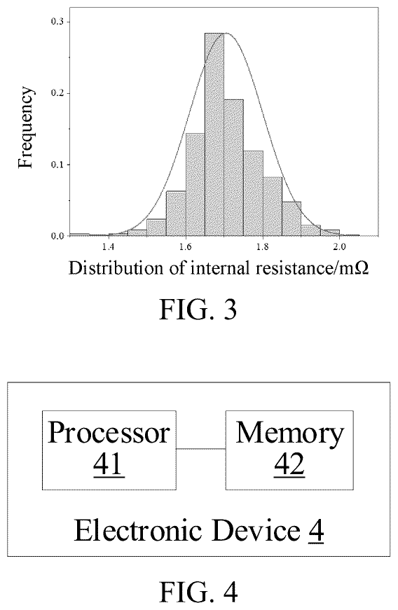

Refer to FIG. 3, which is a statistical distribution diagram of internal resistance of a method for estimating an internal resistance of a lithium battery according to an embodiment of the present disclosure. As shown in FIG. 3, the statistical distribution of internal resistance is obtained through the PSO algorithm, and the internal resistance distribution diagram of the battery after 18 months of use is presented. In the figure, the horizontal axis represents values of internal resistance obtained by different estimations, and the vertical axis represents frequencies of occurrence of the corresponding values, wherein each frequency of occurrence is a number of occurrences during estimation divided by a total number of estimations.

(B2) Treating a distribution of the estimated values of the total internal resistance obtained through estimation as a normal distribution, and taking an expected value of the normal distribution as an expected internal resistance of the battery.

It may be seen from FIG. 3, although the internal resistance obtained through each estimation is slightly different, the distribution of the internal resistance of the battery satisfies a normal distribution, where the internal resistance always fluctuates around the expected value of the distribution of the internal resistance, and the standard deviation of fluctuation is less than 0.1. When the distribution of the internal resistance of the battery satisfies the normal distribution, it may be considered that a mean value of the normal distribution is the internal resistance of the battery.

In an embodiment, after step B of S14, the method for estimating an internal resistance of a lithium battery further comprises:

using a change in the expected value of the normal distribution as a change in the total internal resistance as the lithium battery charges and discharges; and analyzing a deterioration trend of the lithium battery through the change in the total internal resistance.

Specifically, for example, in a first cycle, the normal distribution of the internal resistance of the battery, calculated for a plurality of times, satisfies N(1.3,0.05), and in a 100th cycle, the internal resistance satisfies N(1.44,0.07), and then the expected change is (1.44-1.3)/1.3=0.107, which indicates that the internal resistance has increased by about 10% on average.

The scope of the method for estimating an internal resistance of a lithium battery of the present disclosure is not limited to the order of performing the steps as described in the present disclosure. Solutions implemented by increasing or decreasing steps and replacing steps in the prior art based on the principles of the present disclosure all fall within the scope of the present disclosure.

The present disclosure further provides a non-transitory computer-readable storage medium, storing a computer program. When the computer program is executed by a processor, the method for estimating an internal resistance of a lithium battery is implemented.

A person of ordinary skill in the art may understand that all or a part of the steps for implementing the above method embodiments may be completed by hardware related to the computer program. The foregoing computer program may be stored in a computer-readable storage medium. When the program is executed, steps of the foregoing method embodiments are performed. The foregoing computer-readable storage medium comprises various computer storage media such as a ROM, a RAM, a magnetic disk, an optical disk, or the like that can store program code.

Refer to FIG. 4, which is a block diagram of an electronic device of the present disclosure. As shown in FIG. 4, the electronic device 4 comprises a processor 41 and a memory 42. The memory 42 is configured to store a computer program, and the processor 41 is configured to execute the computer program stored in the memory 42, so that the electronic device 4 performs steps of the method for estimating an internal resistance of a lithium battery.

The above processor 41 may be a general-purpose processor, comprising a central processing unit (CPU), a network processor (NP), and the like. The processor may alternatively be a digital signal processor (DSP), an application specific integrated circuit (ASIC), a field programmable gate array (FPGA) or another programmable logic device, a discrete gate or a transistor logic device, or a discrete hardware assembly.

The memory 42 may comprise a random-access memory (RAM), or may comprise a non-volatile memory, for example, at least one magnetic disk storage.

In practical application, the electronic device may be a computer comprising components such as a memory, a storage controller, one or more processing units (CPU), a peripheral interface, an RF circuit, an audio circuit, a speaker, a microphone, an input/output (I/O) subsystem, a display screen, another output or control device, and an external port. The computer comprises, but is not limited to, personal computers such as a desktop computer, a notebook computer, a tablet computer, a smart phone, and a personal digital assistant (PDA). In some other implementations, the electronic device may further be a server. The server may be arranged on one or more physical servers according to various factors such as functions and loads, or may be a cloud server composed of distributed or centralized server clusters, which is not limited in this embodiment.

Based on the above, the method for estimating an internal resistance of a lithium battery, the storage medium, and the electronic device may be applied in various working environments to solve the problem that it is difficult to accurately estimate the internal resistance of the battery in various working environments. The present disclosure can be applied in various working environments, for example, a non-constant-current/voltage working environment. The internal resistance estimation of the present disclosure has high accuracy, and the internal resistance distribution of the battery can be accurately obtained from test results. When the distribution of the internal resistance of the battery satisfies a normal distribution, it may be considered that the expected value of the distribution is the internal resistance of the battery. Implementation of the method of the present disclosure requires a very small memory space of only 15 kB, and doesn't interfere with other functions during practical application. It also operates quickly in real-time. For example, it takes only about 2 seconds to process a whole day's data for a single battery using the method. The present disclosure effectively overcomes various disadvantages in the prior art, and has high industrial utilization value.

The above embodiments describe the principle and efficacy of the present disclosure by using examples, and are not used to restrict the present disclosure. Any person familiar with this technology can modify or change the above embodiments without departing from the spirit and scope of the present disclosure. Therefore, all equivalent modifications or changes made by a person skilled in the art without departing from the spirit and technical ideas disclosed in the present disclosure shall still be covered by the claims of the present disclosure.

What is claimed is:

1. A method for estimating an internal resistance of a lithium battery, comprising:
S11: continuously sampling a current and a voltage of the lithium battery at a preset sampling interval;
S12: inputting the current and the voltage of the lithium battery to a previously constructed internal resistance estimation equivalent circuit model, determining to-be-estimated parameters of the internal resistance estimation equivalent circuit model, and determining expressions of an open circuit voltage and an internal resistance of the lithium battery comprising the to-be-estimated parameters;
S13: obtaining a range of each of the to-be-estimated parameters of the internal resistance estimation equivalent circuit model based on an adaptively adjusted memory factor of the internal resistance estimation equivalent circuit model; and
S14: S14A, inputting the range of each of the to-be-estimated parameters to an internal resistance distribution model to obtain a total internal resistance of the lithium battery, and S14B, determining a statistical distribution of the total internal resistance of the lithium battery by repeatedly running the internal resistance distribution model, with different numbers of single estimations carried out during each repetition of running the internal resistance distribution model, to obtain different estimated values of the total internal resistance of the lithium battery.

2. The method as in claim 1, wherein S12 further comprises:
inputting the current and the voltage of the lithium battery to an input matrix of the internal resistance estimation equivalent circuit model; and
completing iterative calculation of the internal resistance estimation equivalent circuit model by using the adaptively adjusted memory factor, to determine the expressions of the open circuit voltage and the internal resistance of the lithium battery, wherein the expression of the open circuit voltage is obtained by polynomial fitting, which is a polynomial of the open circuit voltage.

3. The method as in claim 2, wherein S13 further comprises:
adjusting the adaptively adjusted memory factor to determine ranges of polynomial coefficients of each order in the polynomial of the open circuit voltage.

4. The method as in claim 3, wherein the internal resistance is the total internal resistance, and comprises an ohmic internal resistance and a polarization internal resistance, wherein the internal resistance distribution model comprises a particle swarm optimization (PSO) model, wherein S14A further comprises:
S14A1, deriving an expression of a terminal voltage which is a function of the total internal resistance and the ranges of the polynomial coefficients, wherein the expression of the terminal voltage serves as an objective function; and
S14A2, continuously moving and adjusting each particle of the PSO model within the ranges of the polynomial coefficients, and determining the total internal resistance of the lithium battery according to a corresponding value of the objective function.

5. The method as in claim 4, wherein the corresponding value of the objective function is a difference between the terminal voltage and the voltage sampled at S11, wherein S14A2 further comprises:
continuously moving and adjusting each particle within the ranges of the polynomial coefficients until a smallest difference between the terminal voltage and the voltage sampled at S11 is obtained; and
for each particle, using its present position corresponding to the smallest difference as an optimal position of the particle, and using corresponding values of the polynomial coefficients as optimal solutions, which are then substituted into the expression of the internal resistance to obtain a value of the total internal resistance of the lithium battery.

6. The method as in claim 1, wherein S14B comprises:
using the different estimated values of the total internal resistance obtained through each estimation as a horizontal axis, and using frequencies of occurrence of the different values of the total internal resistance as a vertical axis, wherein each frequency of occurrence is a number of times a corresponding estimated value of the total internal resistance occurs during estimation divided by a total number of single estimations carried out; and
treating a distribution of the estimated values of the total internal resistance obtained through estimation as a normal distribution, and taking an expected value of the normal distribution as an expected internal resistance of the battery.

7. The method as in claim 6, after S14B, further comprising:
using a change in the expected value of the normal distribution as a change in the total internal resistance as the lithium battery charges and discharges; and
analyzing a deterioration trend of the lithium battery through the change in the total internal resistance.

8. The method as in claim 1, wherein S11 further comprises:
creating the internal resistance estimation equivalent circuit model by using a first-order RC equivalent circuit, wherein the internal resistance estimation equivalent circuit model comprises mathematical models for the open circuit voltage and the internal resistance of the lithium battery.

9. A non-transitory computer-readable storage medium, storing a computer program, wherein when the computer program is executed by a processor, the method for estimating an internal resistance of a lithium battery as in claim 1 is implemented.

10. An electronic device, comprising a processor and a memory, wherein
the memory is configured to store a computer program, and the processor is configured to execute the computer program stored in the memory, so that the electronic device performs the method for estimating an internal resistance of a lithium battery as in claim 1.
